(19) United States
(12) Patent Application Publication
(10) Pub. No.: US 2006/0252262 A1
(43) Pub. Date: Nov. 9, 2006

(54) Semiconductor structures having via structures between planar frontside and backside surfaces and methods of fabricating the same

(75) Inventor: Hooman Kazemi, Thousand Oaks, CA (US)

Correspondence Address: KOPPEL, PATRICK & HEYBL, 555 ST. CHARLES DRIVE, SUITE 107, THOUSANDS OAKS, CA, 91360, US

(73) Assignee: ROCKWELL SCIENTIFIC LICENSING, LLC

(21) Appl. No.: 11/121,504

(22) Filed: May 3, 2005

(51) Int. Cl. H01L 21/44

(52) U.S. Cl. 438/667

(57) ABSTRACT

Methods of backside planarization processes have been developed to gain a high resolution backside process lithography and to make possible the development of dual faced MMICs and circuits. Two different processes have been employed to planarize via structures of various depths, one including epoxy-fill via structures with depths of 10 mils and the other solid-metal via structures with depths of 3.5 mils. Application of a wafer fabricated using methods of the present invention has been demonstrated in a monolithic circuit, where bias control to the frontside of the wafer was established by solder bumps on the planarized backside surface of a wafer including epoxy-filled via structures.

### BACKGROUND OF THE INVENTION

1. Field of the Invention

This invention relates to semiconductor structures including wafers and circuits, and more particularly to semiconductor structures having via structures between planar frontside and backside surfaces.

2. Description of Related Art

As the application of microwave and millimeter wave products become increasingly more complex, integrated system solutions are required for improving performance criteria. Such solutions typically require a reduction in overall system size which inevitably entails size reductions at the component level. A reduction in system components may be achieved through more efficient utilization of the backside surface of component circuits.

On such application of microwave and millimeter wave products is the electronically steered antenna technology. In this technology active MMIC circuits are incorporated in the antenna itself. See for example, Higgins, J. A.; Hao Xin; Sailer, A.; Rosker, M.; “Ka-band waveguide phase shifter using tunable electromagnetic crystal sidewalls” Microwave Theory and Techniques, IEEE Transactions on, Volume: 51, Issue: 4, April 2003 Pages: 1281-1288. M. E. Davis, “Space Based Radar Core Technology Challenges for Affordability,” 2001 Core Technologies for Space Systems Conference Dig., Colorado Springs, Colo., November 2001. McPherson, D.; Bates, D.; Lang, M.; Edward, B.; Helms, D.; Military Communications Conference, “Active phased arrays for millimeter wave communications applications” 1995. MILSOM '95, Conference Record, IEEE, Volume: 3, 5-8 November 1995 Pages: 1061-1065 vol. 3. Lemons, A.; Lewis, R.; Milroy, W.; Robertson, R.; Coppedge, S.; Kastle, T.; “W-band CTS planar array,” Microwave Symposium Digest, 1999 IEEE MTT-S International, Volume: 2, 13-19 June 1999 Pages: 651-654 vol. 2.

Generally, the MMIC circuits are designed in microchip or grounded coplanar waveguide structures which require substrate vias to connect frontside devices to ground on the backside of the wafer. Using conventional methods, once these via structures are created, deep voids remain in the backside of the wafer in the area of the via structures.

During subsequent chip fabrication processes, photoresist flows into the voids and is not developed when exposed. An uneven lithography results and the resolution of subsequent backside fabrication steps dependent on the lithography are compromised. For example, if large size solder bumps are required on the backside, the solder bumps may overlap with the deep voids. Any photoresist trapped in the voids may eventually outgas and cause the solder bumps to separate from the backside, resulting in reliability issues.

### SUMMARY OF THE INVENTION

Briefly, and in general terms, the invention is directed to semiconductor structures with via structures between planar frontside and backside surfaces and methods of fabricating such structures. In one aspect of the invention, a semiconductor structure is fabricated by forming vias through a semiconductor substrate having a frontside surface and a backside surface. A conductive material is deposited in the vias to establish a conductive path between the frontside surface and the backside surface. The remainder of the vias are filled with a core material. Portions of the conductive material and the core material are removed so the backside surface of the substrate is substantially planar with respect to the conductive material and the core material.

In another aspect of the invention, a semiconductor structure is also fabricated by forming vias through a semiconductor substrate having a frontside surface and a backside surface. The vias are filled with material, including at least partially with a conductive material to establish a conductive path between the frontside surface and the backside surface. Portions of the conductive material are removed so the backside surface of the substrate is substantially planar with respect to the conductive material.

In another aspect, the invention relates to a semiconductor structure that includes a substrate having a frontside surface and a substantially planar backside surface and a plurality of via structures through the substrate. The via structures include an electrically conductive frontside structure forming part of the frontside surface, and an electrically conductive core structure electrically connected with the frontside structure. The core structure includes a backside structure that forms part of the backside surface.

In yet another facet, the invention relates to a semiconductor structure that includes a substrate with a frontside surface and a substantially planar backside surface. The structure also includes a plurality of vias through the substrate. The vias are filled with a via material that includes, at least partially, a conductive material. The conductive material establishes a conductive path between the frontside surface and the backside surface. The backside surface of the substrate is substantially planar with respect to the via material.

These and other aspects and advantages of the invention will become apparent from the following detailed description and the accompanying drawings which illustrate by way of example the features of the invention.

### BRIEF DESCRIPTION OF THE DRAWINGS

FIG. 1 is a view of the frontside surface of a semiconductor structure according to the invention;

FIG. 2 is a sectional, profile view of the semiconductor structure of FIG. 1 along lines 2-2;

FIG. 3 is a view of the backside surface of the semiconductor structure of FIG. 1;

FIG. 4 shows a process flow for fabricating the semiconductor structure of FIG. 1;

FIGS. 5-12 are sectional, profile views of various stages of the semiconductor structure process flow of FIG. 4;

FIG. 13 is an enlarged section of the backside surface shown in FIG. 3;

FIG. 14 is a view of the frontside surface of another semiconductor structure according to the invention;

FIG. 15 is a sectional, profile view of the semiconductor structure of FIG. 14 along lines 15-15;

FIG. 16 is a view of the backside surface of the semiconductor structure of FIG. 14;

FIG. 17 shows a process flow for fabricating the semiconductor structure of FIG. 13;

FIGS. 18-19 are sectional, profile views of two of the stages of the semiconductor structure process flow of FIG. 17; and

FIG. 20 is a view of the backside surface of a chip including a semiconductor structure of the present invention.

### DETAILED DESCRIPTION OF THE PREFERRED EMBODIMENTS

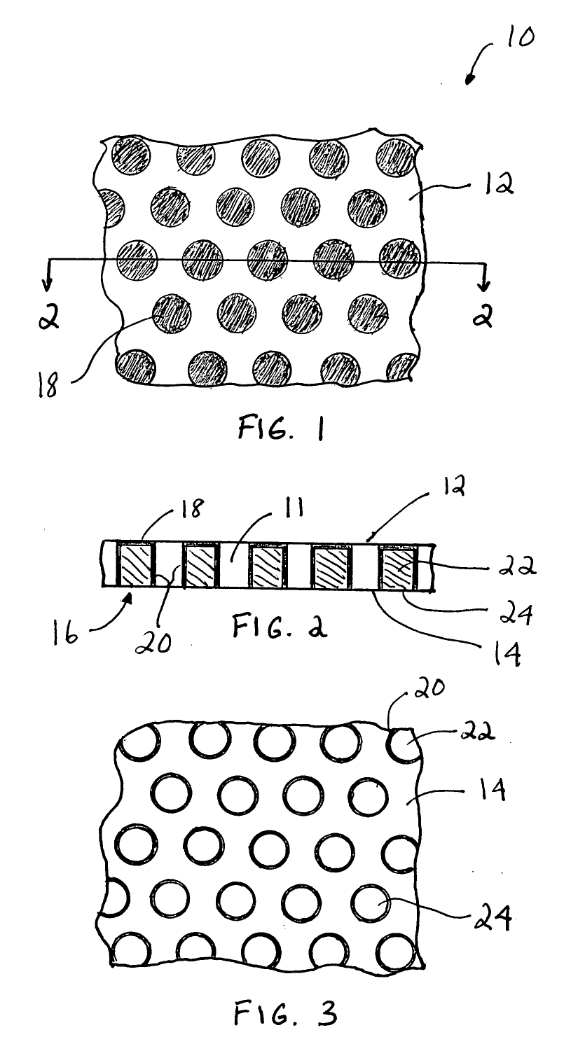

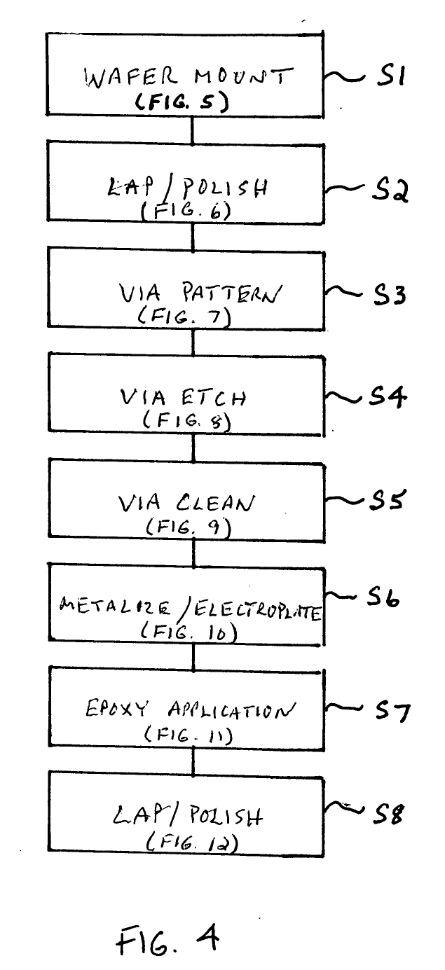

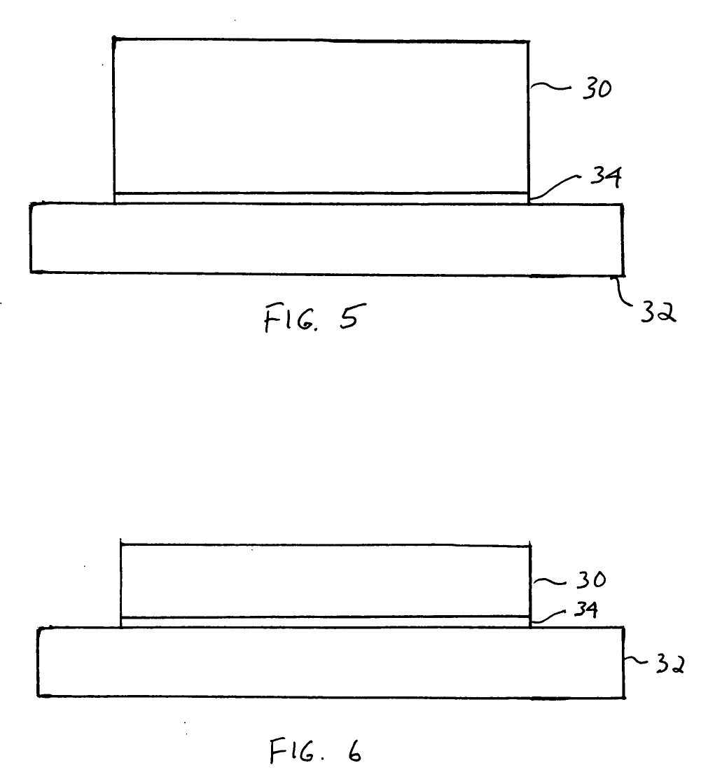

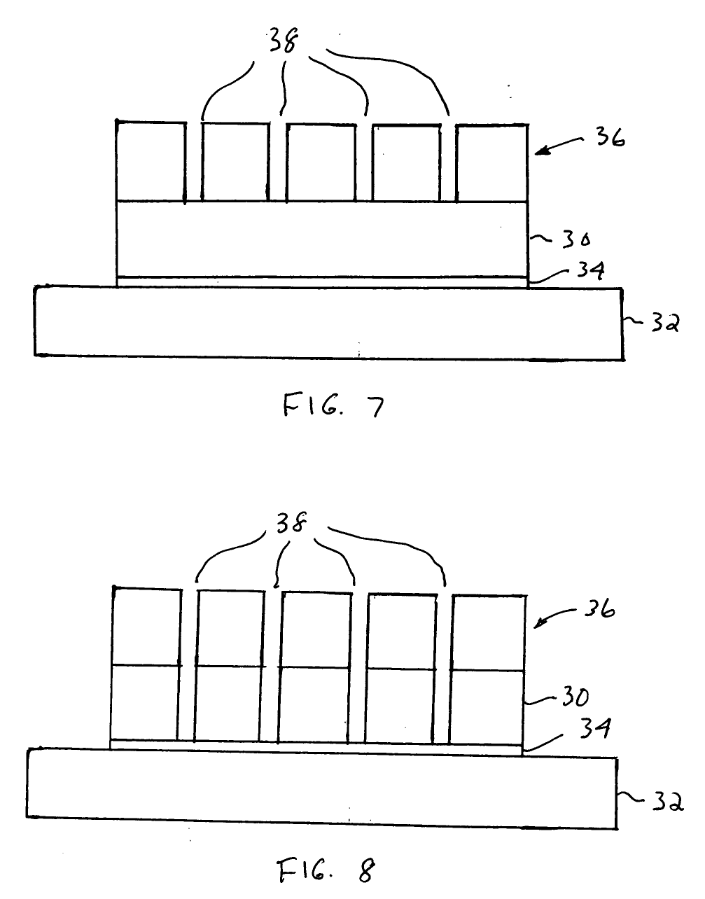

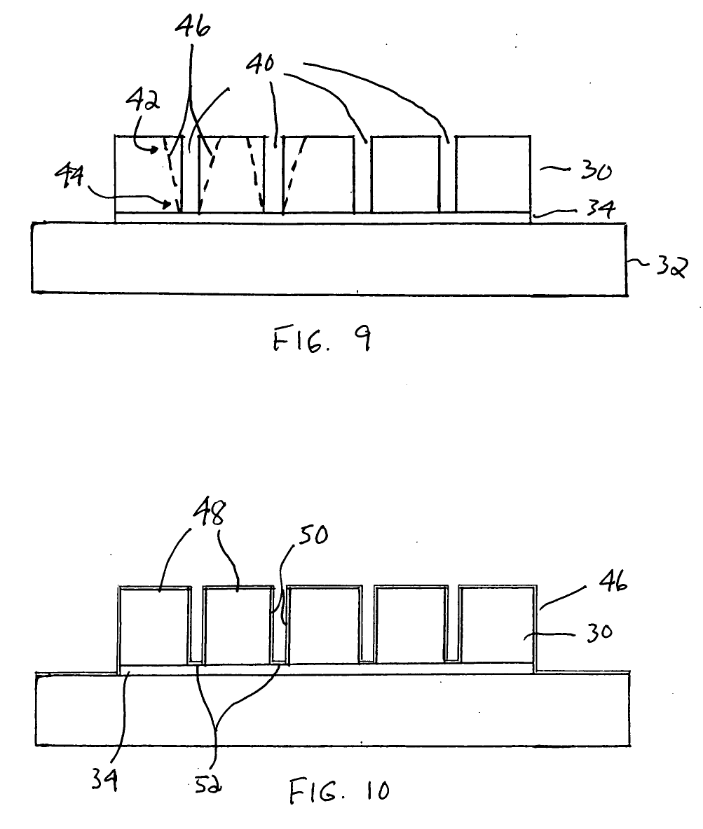

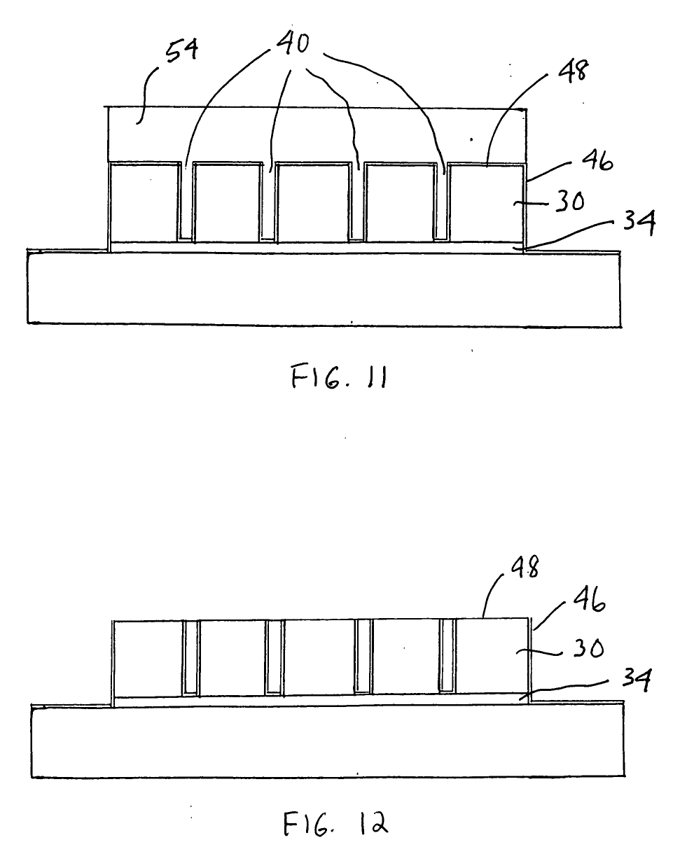

Referring now to the drawings and particularly to FIGS. 1, 2 and 3, there is shown a semiconductor structure 10 configured in accordance with the invention. The structure 10 includes a substrate 11 having a substantially planar frontside surface 12, a substantially planar backside surface 14 and a plurality of via structures 16. “Planar” as used herein means a surface having a profile that is within a specified deviation tolerance, e.g., within 2-3 microns, that is adequate for further fabrication.

In a preferred embodiment, the via structures 16 are substantially circular in cross section. In other embodiments the via structures 16 may have anyone of numerous other shapes. The via structure 16 includes a frontside 18 and one or more sidewalls 20. The frontside 18 is substantially planar with respect to the planar frontside surface 12 of the substrate 11 and may be described as forming part of the frontside surface of the structure 10.

Each of the frontside 18 and sidewalls 20 are formed of a conductive material. Any conductive material may be used, with the selection of such material possibly dependent on the desired electrical and thermal characteristics of the semiconductor structure. In one configuration, the conductive material is gold, which is low resistance. In other configurations, where a more thermally conductive structure is desired, the conductive material may be copper or silver.

The via structures 16 also include a core 22 that abuts the inside surfaces of the frontside 18 and the sidewalls 20. The core 22 itself includes a backside 24 that is substantially planar with respect to the planar backside surface 14 of the substrate 11 and may be described as forming part of the backside surface of the structure 10. The core 22 may be formed of a material that is either electrically conductive or not electrically conductive. Such materials are referred to herein as “conductive” and “non-conductive” materials, respectively.

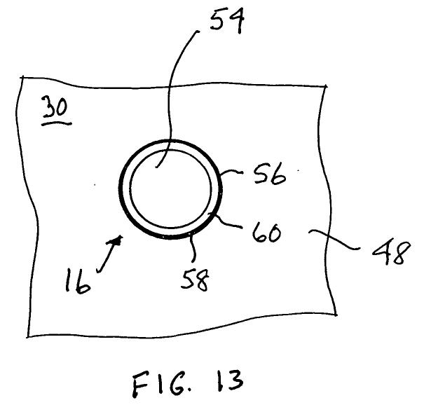

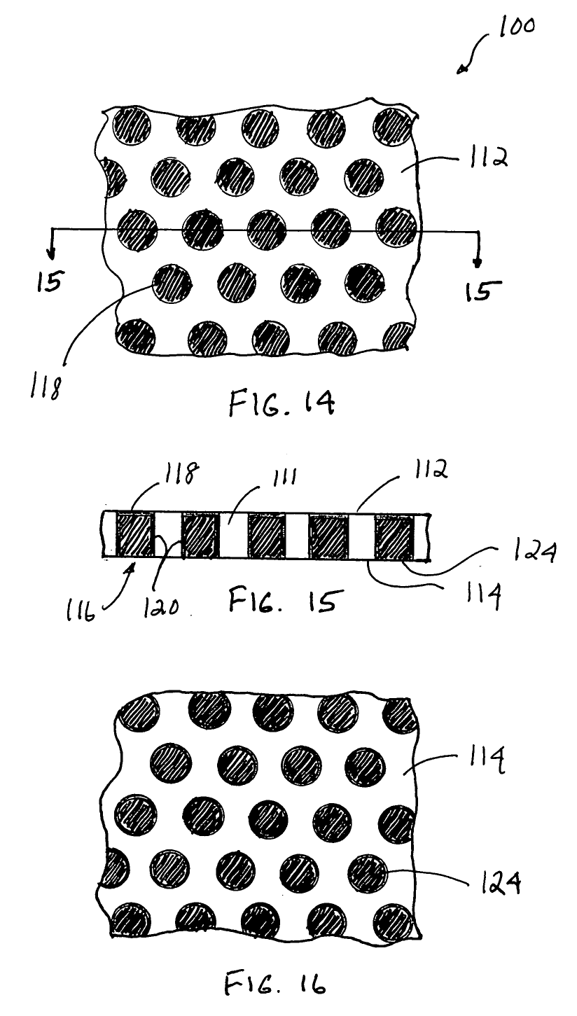

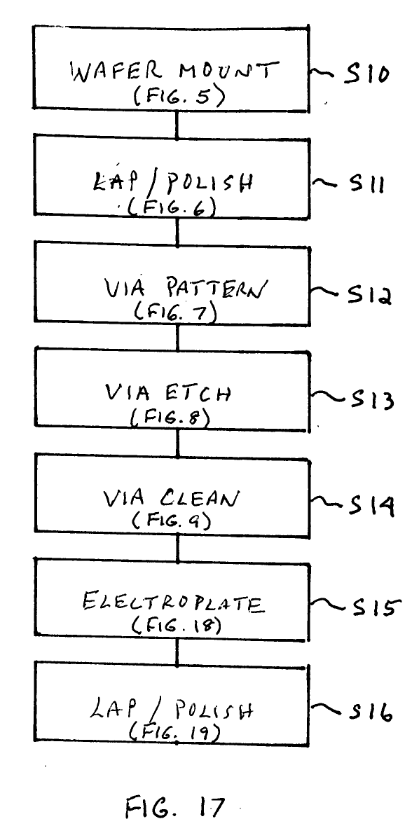

With reference to FIG. 4 and the various figures further referenced therein, a semiconductor circuit like that shown in FIGS. 1, 2 and 3, is formed using various processes. Many of these processes are well known to those of ordinary skill in the art and the details of these processes are, therefore, not described. It should be noted that elements of the circuits of FIGS. 1, 2 and 3 are illustrated at a different scale than corresponding elements shown in FIGS. 5-12.

In step S1 (FIG. 5), a substantially flat semiconductor substrate 30 is flat mounted on a substantially flat carrier 32 using a low temperature wax (not shown). In a preferred embodiment, the side of the substrate 30 abutting the carrier 32 is coated with one or more layers of conductive material 34 that serve as a frontside metallization pad, which may be formed of any metal. In one configuration, the conductive material 34 is gold. The semiconductor substrate 30 may be formed of gallium arsenide (GaAs), silicone (Si), silicone carbide (SiC), indium phosphide (InP) or any other suitable semiconductor material. The carrier 32 may be formed of sapphire, glass, quartz, or of a semiconductor material, e.g., GaAs, Si, SiC, InP.

In step S2 (FIG. 6), the semiconductor substrate 30 is measured, lapped and polished to a desired thickness using a grit-based lapping compound and chemical polishing solution. An example of a chemical polishing solution is Sodium Hypochlorite. The substrate 30 may be lapped to a desired thickness, which is typically at least 3 mils. In one process test run, the substrate 30 was lapped to a thickness of 10.5 mils.

In step S3 (FIG. 7), a via mask is patterned into a layer of photoresist 36. The material is poured onto the semiconductor substrate 30, is spun and baked repeatedly as necessary, to achieve a desired thickness. In one process test run, a photoresist layer 36 approximately 25 um thick was formed using photoresist material AZ-4620 (available from AZ Electronic Material).

A via pattern 38 is formed in the photoresist layer 36 using well known techniques, such as exposing the photoresist to deep ultraviolet (DUV) through a glass mask defining the via pattern. After deep ultraviolet (DUV) post exposure, the photoresist layer 36 is hard baked to conserve its pattern contrast.

In step S4 (FIG. 8), the via pattern 38 in the photoresist layer 36 is etched through to the frontside metallization pad 34. The etching is done using a dry etch process, such as a reactive ion etch (RIE), laser beam, electron cyclotron response (ECR) and others. In one process test run, an RIE inductively coupled plasma (ICP) assisted dry etch process was used to etch a 4″ GaAs wafer. The etch recipe used during the process was Cl₂-600 sccm-BCL₃-30 sccm, HBr-5 sccm at 900 W power with a chamber pressure of 2-mTorr. The recipe is capable of greater than 2.5 um/min etch rate for depths of 10 mils through the via mask 36. The uniformity of the etch depth across the 4″ wafer was 5% with outer regions of the substrate 30 etching faster than the inner regions. In order to ensure complete formation of vias at the inner region of the substrate 30, an over-etch in the outer regions was performed. The over etch in these regions essentially stopped at the metallization pad due to the difference in etch rates between the metallization pad and the substrate material.

In step S5 (FIG. 9), the substrate is cleaned in a hot solvent solution having a temperature between 100-130° C. The solution removes any etch polymer that may be present in the vias 40 as a result of the dry etch process. The solution also removes the photoresist layer 36 (FIG. 8). At this point, the vias 40 have been opened through to the frontside metallization pad 34. During the etching process, the backside portions 42 of the vias 40 are etched for a longer duration than the frontside portions 44. Thus, the walls 46 of the vias 40 assume a truncated cone configuration, as shown by the phantom lines in FIG. 9. The opening at the frontside 44 replicates the original size of the photoresist mask 36 (FIG. 8) vias. In one process test run, the frontside opening 44 was approximately 5 mils in diameter. For ease in illustration, except for the phantom lines in FIG. 9, the vias 40 are shown in all figures with substantially straight sidewalls.

In step S6 (FIG. 10), a layer of conductive material 46 is deposited on the semiconductor substrate 30 to cover all exposed surfaces of the substrate, including the backside surface 48, the via sidewalls 50 and the backside portions 52 of the frontside metallization pad 34 exposed by the vias 40. In a preferred embodiment, this layer 46 includes two layers: An initially deposited first layer that functions as a metal-plating base layer, or seed layer, and a subsequently deposited second layer of conductive material that provides low resistance contact between the frontside and backside of the wafer 30.

The seed layer may be deposited on all exposed surfaces of the substrate 30 using any of several known methods such as electron beam evaporation or sputter deposition. The material of the seed layer is selected based on its ability to adhere to the wafer surfaces. In one process test run, a seed layer was formed of TiAu. Titanium adheres to the substrate 30 and is a base metal for the subsequent plating processes used to deposit the second layer of conductive material. Examples of alternate seed-layer materials include titanium/tungsten/gold, nickel, gold and chrome.

The second layer of conductive material is deposited using well know plating processes. “Plating” as used herein refers to both electroplating and electroless plating processes that are used to deposit metal films. During an electroplating process, the substrate 30, including the seed layer, is submerged in a liquid bath that includes ions of the metal that will form the second layer. An external power supply is used to apply a potential between an electrode in the liquid bath and the seed layer. The applied potential drives a reduction reaction of the metal ions at the seed layer. Over time, electroplated metal forms the second layer. In one process test run, a 3 um thick layer of gold was plated to a TiAu seed layer.

In an electroless plating process the deposition of the second-layer metal is not controlled by an external power supply, but rather the deposition is initiated by a chemical reduction reaction that is catalyzed by the metal that is being deposited.

In step S7 (FIG. 11), a core material 54 is applied on the backside surface 48 of the semiconductor substrate 30 to fill the vias 40. As previously stated, the core material 54 may be either conductive or non-conductive. The core material 54, however, is generally of a liquid form that is capable of being mechanically applied to the wafer; capable of filling the vias 40, such as through the affect of gravity with possible assistance by mechanical movement or pressure; and capable of having portions of it subsequently mechanically removed from the substrate.

Possible non-conductive materials include polymer-based materials. In one process test run, an organic polymer-based epoxy, EpoTek 360 part A and B, was applied on the substrate. Possible conductive material include metal-based epoxies, such as a silver epoxy. In either case, substantially all air bubbles trapped in the core material 54 are removed by applying a low pressure outgas vacuum process. The substrate is then baked to cure and solidify the core material at 100° C. for 3 hours.

In-step S8 (FIGS. 11 and 12), the backside surface 48 of the semiconductor substrate 30 is lapped and polished to remove the excess core material 54 and the portions of the conductive layer 46 that are on, or extend above, the backside surface 48. During this process the substrate 30 is mounted flat, therefore it can be planarized accurately during the process by means of lapping and polishing.

Alternatively, the backside surface 48 may be lapped and polished to remove only the excess core material 54 while leaving a layer of conductive material. As describe later, with respect to FIG. 20, this layer of conductive material may be further processed to form groups of electrically connected via structures.

At anytime prior to or after completion of further backside processing, the carrier 32 is separated from the substrate 30 and the metallization pad 34. The metallization pad 34 is also typically removed to expose the frontsides 18 of the via structures 16 and to allow for device mounting on the frontside.

With reference to FIG. 13, after step S8, elements of the via structures 16 are visible on the backside surface 48. The outer boundary 56 of the via structure 16 represents the outer boundary of the via that was etched into the semiconductor substrate 30. The concentric rings 58, 60 represent the two-part conductive layer 46. The outer ring 58 is the first layer of conductive material or seed layer (e.g., TiAu) and the inner ring 60 is the second layer of conductive material (e.g., Au) that is deposited on the seed layer. The section bounded by the inner ring 60 is the non-conductive core material 54, e.g., epoxy. The planar backside surface 48 can now be used for high definition photolithography with the via structure 16 providing for electrical connection between the backside and the frontside through the conductive rings 58, 60 (i.e., the conductive layer 46 passing through the wafer).

In an alternate configuration, the vias structures 16 (FIGS. 1, 2 and 3) may be formed entirely of a conductive material capable of being mechanically applied to the substrate 11, such as an silver-based epoxy. In this configuration, the metallization/electroplating process (FIG. 4, S10) is eliminated and the conductive material is applied to the substrate 11 to fill the vias 16. The conductive material is then out gassed, cured and lapped to create a backside 24 that is substantially planar with the backside surface 14 of the substrate.

Although a via structure including a core material, such as that described above, is suitable for all via dimensions and wafer heights, it may be desirable to have via structures that are filled with an electrically conductive material, such as a metal. Such via structures provide, not only a low resistive path between the backside and the frontside of the structure, but also a more efficient heat transfer. This is particularly beneficial when the structure is used for high power MMIC applications.

With reference to FIGS. 14, 15 and 16, in another embodiment of the invention, the semiconductor circuit includes via structures that are formed of electrically conductive material. This configuration of a semiconductor structure 100 includes a substrate 111 with a substantially planar backside surface 112, a substantially planar frontside surface 114 and a plurality of via structures 116.

The via structures 116 include a frontside 118 and one or more sidewalls 120. The frontside 118 is substantially planar with respect to the planar frontside surface 112 of the substrate 111 and may be described as forming part of the frontside surface of the structure 100. The via structures 116 also include a backside 124 that is substantially planar with respect to the planar backside surface 114 of the substrate 111 and may be described as forming part of the backside surface of the circuit 100.

With reference to FIG. 17 and the various figures referenced therein, a semiconductor structure like that shown in FIGS. 14, 15 and 16, is formed using various processes. The wafer mount (S10), lap/polish (S11), via pattern (S12), via etch (13) and via clean (S14) steps of the process are substantially the same as steps S1 through S5 of FIG. 4. Therefore, descriptions of these steps are not repeated. Again, it should be noted that elements of the circuits of FIGS. 14, 15 and 16 are illustrated at a different scale than corresponding elements shown in FIGS. 5-9 and 18-19.

In step S15 (FIG. 18) a conductive material 154 is deposited in the vias 140. In one configuration, layers of the conductive material 154 are deposited on the portions 152 of the metallization pad 34 that are exposed by the vias 140 using a plating process, similar to those previously described. In this case the substrate 30 acts like a mask and guides the plating through the vias 140.

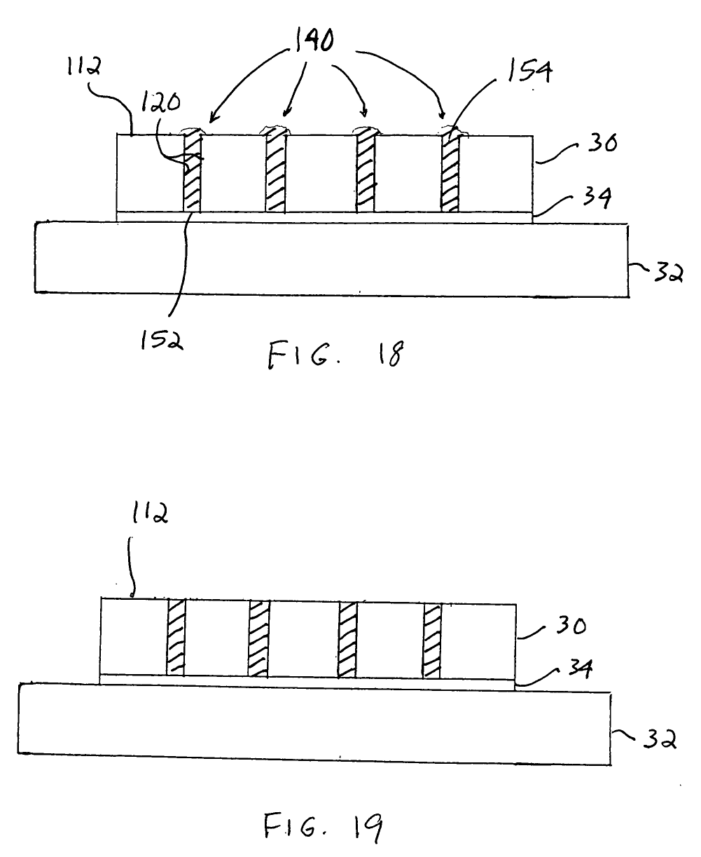

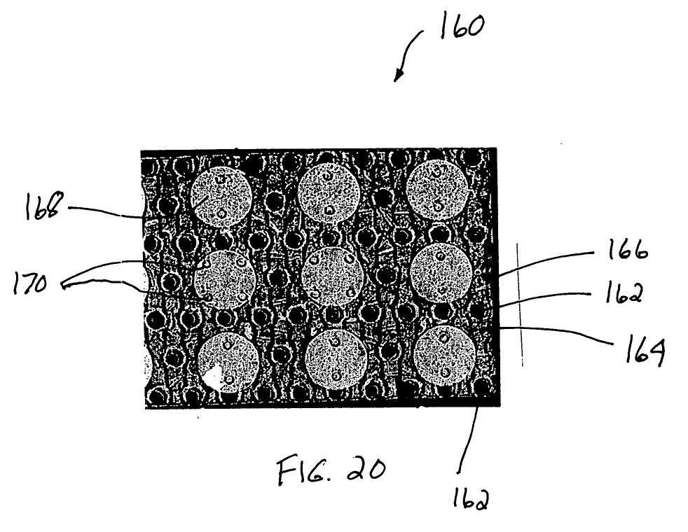

With continue reference to FIG. 18, once the plating process is completed it is possible that some of the conductive material 154 may have plated beyond the backside surface 112 of the wafer 30. Accordingly, at step S8 (FIG. 19), the substrate 30 is lapped and polished in order to obtain a substantially planarized backside surface 112. During this process the substrate 30 is mounted flat, therefore it can be planarized accurately during the process by means of lapping and polishing.

At anytime prior to or after completion of further backside processing, the carrier 32 is separated from the substrate 30 and the metallization pad 34. The metallization pad 34 is also typically removed to expose the frontsides 118 of the via structures 116 and to allow for device mounting on the frontside.

In one process test run of FIG. 17, a semiconductor structure like that shown in FIGS. 14, 15 and 16, was formed using a GaAs substrate 30. The substrate 30 was lapped to a thickness of approximately 3.5 mil to target typical MMIC applications and vias 140 having diameters of approximately 50 um were dry etched into the substrate. Because of the smaller via 140 depth, compared to the process of the embodiment of FIGS. 1, 2 and 3, (which had via depths of 10.5 mil) the dry etch recipe was less aggressive with respect to chamber pressure. Vias structures 116 were then formed by electroplating layers of gold into the via openings. The electroplating solution used was “Technic 25E,” which is available from Technic, Inc.

Because of the cross-sectional area of the vias 140, the current density used during the electroplating process was adjusted in order to gradually build up layers in the vias. Generally, the smaller the cross-sectional area the lower the current density. This is important because if too high of a current density is used, the sidewalls 120 of the vias 140 may plate faster than the center of the vias and voids may appear in the via structure 116. Excess portions of the layers 154 were removed to form solid via structures 116 having backside surfaces 118 substantially planar with respect to the backside surface 112 of the structure 100.

With reference to FIG. 20, one possible application for the semiconductor circuits of the present invention relates to electromagnetic crystal (EMXT) chips. The EMXT chip may be designed to perform as a periodic structure with high surface impedance in a waveguide transmission line, similar to that disclosed in Xin, H.; Kazemi, H.; Lee, A. W.; Higgins, J. A.; Rosker, M. J.; “Low-loss monolithic tunable electromagnetic crystal surfaces with planar GaAs Schottky diodes” Antennas and Propagation Society International Symposium, 2003. IEEE, Volume: 2, Jun. 22-27, 2003, Pages: 435-438. One such chip has metal stripes (not shown) on the frontside of the wafer that are loaded with varactor diodes which are alternately bias from the backside 160 of the wafer through via structures 162, to vary the frontside surface impedance.

The thickness of the chip is a function of its frequency and at Ka-band is approximately 10 mils in depth. As a bias is applied between these frontside stripes a variable surface impedance to the impinging electromagnetic field is created. This feature can be used to electronically steer the beam for compact, low-cost and high-performance phased array antennas.

Multiple via structures 162 are required for each strip to establish proper signal-ground condition. In this application, the frontside metallization pad 34 is left on the wafer and is used to connect common potential via structures 162 on the backside 166 of the wafer. These collections of via structures 162 are created by removing portions of the metallization pad 34 to form a plurality of conduction paths 164 that are electrically isolated from each other. Each conduction path 164 encompasses a plurality of via structures 162.

These conduction paths 164 are separated by streets 166 that are typically only 10 um wide. In FIG. 20, it is noted that the removal of the 10 um wide portions of the metallization pad expose the underlying wafer, which in effect form the streets 166. In order to define such long 10 um line widths across a small chip, e.g., 7 mm chip, it is important to have a planarized backside 160 to ensure continuity of the line. Elevated solder pads 168 are then positioned over and electrically connected to a conduction path 164 by solder connections 170. Using these solder pads 168, the chip may be solder bumped on its housing and thus be controlled completely from the backside of the chip.

Methods of backside planarization processes have been developed to gain a high resolution backside process lithography and to make possible the development of dual faced MMICs and circuits. Two different processes have been employed to planarize via structures of various depths, one including epoxy-fill via structures with depths of 10 mils and the other solid-metal via structures with depths of 3.5 mils. Application of a wafer fabricated using methods of the present invention has been demonstrated in a monolithic circuit, where bias control to the frontside of the wafer was established by solder bumps on the planarized backside surface of a wafer including epoxy-filled via structures.

It will be apparent from the foregoing that while particular forms of the invention have been illustrated and described, various modifications can be made without departing from the spirit and scope of the invention. Accordingly, it is not intended that the invention be limited, except as by the appended claims.

We claim:

1. A method of forming a semiconductor structure comprising:
forming vias through a semiconductor substrate having a frontside surface and a backside surface;
depositing conductive material in the vias to establish a conductive path between the frontside surface and the backside surface;
filling the vias with a core material; and
removing portions of the conductive material and the core material so the backside surface of the substrate is substantially planar with respect to the conductive material and the core material.

2. The method of claim 1 wherein the vias have sidewalls and depositing conductive material in the vias comprises depositing a layer of conductive material on the sidewalls.

3. The method of claim 2 wherein depositing a layer of conductive material on the sidewalls comprises:
depositing a seed layer on the sidewalls; and
depositing the conductive material on the seed layer.

4. The method of claim 3 wherein the seed layer is deposited on the sidewalls by sputtering.

5. The method of claim 3 wherein the conductive material is deposited on the seed layer using a plating process.

6. The method of claim 2 further comprising depositing a layer of conductive material across the openings of the vias adjacent the frontside surface of the substrate.

7. The method of claim 6 wherein the layer of conductive material is deposited across the openings of the vias by:
depositing a metallization pad on the frontside surface prior to forming the vias; and
depositing the layer of conductive material on the portions of the metallization pad exposed by the vias.

8. The method of claim 7 wherein the layer of conductive material is deposited on the exposed portions of the metallization pad by:
depositing a seed layer on the exposed portions of the metallization pad; and
depositing the conductive material on the seed layer.

9. The method of claim 8 wherein the seed layer is deposited on the metallization pad by sputtering.

10. The method of claim 8 wherein the conductive material is deposited on the seed layer using a plating process.

11. The method of claim 1 wherein filling the vias with a core material comprises applying a material on the backside surface to fill the vias.

12. The method of claim 11 wherein the material is conductive.

13. The method of claim 11 wherein the material is non-conductive.

14. The method of claim 11 further comprising out gassing the material to form a core structure that is substantially void of air pockets.

15. The method of claim 11 further comprising curing the material.

16. The method of claim 1 wherein portions of the conductive material and the core material are removed by lapping.

17. A method of forming a semiconductor structure comprising:
forming vias through a semiconductor substrate having a frontside surface and a backside surface;
filling the vias with material, including at least partially with a conductive material to establish a conductive path between the frontside surface and the backside surface; and
removing portions of the conductive material so the backside surface of the substrate is substantially planar with respect to the conductive material.

18. The method of claim 17 wherein the via has a frontside opening and a backside opening and filling the vias with conductive material comprises depositing conductive material in the via until the conductive material reaches at least the backside opening.

19. The method of claim 18 wherein depositing conductive material in the via comprises:
depositing a metallization pad on the frontside surface prior to forming the vias; and
depositing layers of conductive material on the portions of the metallization pad exposed by the vias.

20. The method of claim 19 wherein the conductive material is deposited on the metallization pad using a plating process.

21. The method of claim 18 wherein depositing conductive material in the via comprises applying a conductive material on the backside surface and allowing it to fill the vias.

22. The method of claim 21 further comprising out gassing the conductive material to remove substantially all air pockets.

23. The method of claim 21 further comprising curing the conductive material.

24. The method of claim 17 wherein portions of the conductive material are removed by lapping.

25. A semiconductor structure comprising:
a substrate having a frontside surface and a substantially planar backside surface; and
a plurality of via structures through the substrate, having an electrically conductive frontside structure forming part of the frontside surface, and an electrically conductive core structure electrically connected with the frontside structure and including a backside structure forming part of the backside surface.

26. The structure of claim 25 wherein the frontside structure comprises a layer of conductive material.

27. The structure of claim 26 wherein the layer of conductive material is a solid layer across the cross section of the via structures.

28. The structure of claim 26 wherein the layer of conductive material comprises a first layer of conductive material different from a second layer of conductive material.

29. The structure of claim 28 wherein the first layer of conductive material is capable of having the second layer of conductive material deposited thereon using a plating process.

30. The structure of claim 25 wherein the core structure comprises a core material at least partially surrounded by an electrically conductive through-element electrically connected to the frontside structure, parts of the core material and the through-element forming part of the backside structure.

31. The structure of claim 30 wherein the via structure includes at least one sidewall surface and the through-element comprises a layer of conductive material on the sidewall surface.

32. The structure of claim 31 wherein the layer of conductive material comprises a first layer of conductive material different from a second layer of conductive material.

33. The structure of claim 32 wherein the first layer of conductive material is capable of having the second layer of conductive material deposited thereon using a plating process.

34. The structure of claim 30 wherein the through-element encircles the core material and the part of the through-element forming part of the backside structure is an electrically conductive ring.

35. The structure of claim 30 wherein the core material is capable of being mechanically applied to the wafer.

36. The structure of claim 30 wherein the core material is conductive.

37. The structure of claim 30 wherein the core material is non-conductive.

38. The structure of claim 30 wherein the core material is substantially void of air pockets.

39. The structure of claim 25 wherein the core structure comprises a conductive material electrically connected to the frontside structure, part of the conductive material forming part of the backside structure.

40. The structure of claim 39 wherein the frontside structure is formed of a material capable of having the conductive material deposited thereon using a plating process.

41. The structure of claim 39 wherein the conductive material is substantially void of air pockets.

42. The structure of claim 25 wherein the frontside structure and the core structure are the same structure.

43. The structure of claim 42 wherein the same structure is formed of a conductive material that is capable of being mechanically applied to the substrate.

44. A semiconductor structure comprising:
a substrate having a frontside surface and a substantially planar backside surface; and
a plurality of vias through the substrate, the vias filled with a via material, including at least partially with a conductive material to establish a conductive path between the frontside surface and the backside surface, the backside surface of the substrate being substantially planar with respect to the via material.

45. The structure of claim 44 wherein the conductive material is plated metal.

46. The structure of claim 45 wherein the remainder of the via material is conductive.

47. The structure of claim 46 wherein the remainder of the via material is non-conductive.

48. The structure of claim 44 wherein the conductive material is a liquid-based material.

49. The structure of claim 44 wherein the via material is plated metal.

50. The structure of claim 44 wherein the via material is a conductive liquid-based material.
